(19) United States
(12) Patent Application Publication
(10) Pub. No.: US 2023/0369186 A1
(43) Pub. Date: Nov. 16, 2023

(54) POWER MODULE PACKAGE

(71) Applicant: NIKO SEMICONDUCTOR CO., LTD., NEW TAIPEI CITY (TW)

(72) Inventors: Hui-Chiang Yang, TAIPEI HSIEN (TW); CHUNG-MING LENG, New Taipei City (TW); CHIH-CHENG HSIEH, Taoyuan City (TW); Wei-Lun Wang, NEW TAIPEI CITY (TW)

(21) Appl. No.: 18/069,229

(22) Filed: Dec. 21, 2022

(30) Foreign Application Priority Data
May 10, 2022 (TW) 111117390

(51) Int. Cl. H01L 23/498; H01L 25/07; H01L 25/18; H01L 23/31

(52) U.S. Cl. CPC H01L 23/49811; H01L 25/071; H01L 25/18; H01L 23/3121; H01L 2924/13055; H01L 2924/13091; H01L 24/40

(57) ABSTRACT

A power module package is provided. The power module package includes an electronic assembly, a first terminal assembly and a second terminal assembly. The electronic assembly at least includes a substrate. The first terminal assembly includes a first power device terminal, and the second terminal assembly includes a second power device terminal. The first power device terminal and the second power device terminal respectively extend from different surfaces of the substrate to form a height difference therebetween. The first power device terminal includes a first contact section and a first non-contact section. The first contact section is directly connected to the substrate, and the first non-contact section is not in contact with the substrate. The substrate protrudes from the first contact section and extends to a position under the first non-contact section.

### CROSS-REFERENCE TO RELATED PATENT APPLICATION

This application claims the benefit of priority to Taiwan Patent Application No. 111117390, filed on May 10, 2022. The entire content of the above identified application is incorporated herein by reference.

Some references, which may include patents, patent applications and various publications, can be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a power module package, and more particularly to a power module package with high withstand voltage.

### BACKGROUND OF THE DISCLOSURE

The power module can be used in home frequency conversion systems, electric vehicles, and industrial control systems so as to convert electrical energy or control circuits. In some circuits such as voltage conversion circuits, the power modules may need to be operated under high power conditions such as high voltage or high current. Therefore, the power modules are required to have the characteristics of high withstand voltage and high withstand current for operation.

In the related art, the power modules generally have a plurality of terminals for electrically connecting to external circuits. Some of the terminals are used to electrically connect with high-voltage power or high-current load. When the power module is operating at high voltage or high current, the creepage distance and the clearance between two adjacent terminals that are used to connect with high voltage power or high current load must meet specific requirements to avoid current leakage between the two adjacent terminals so as to prevent product reliability from being decreased.

### SUMMARY OF THE DISCLOSURE

In response to the above-referenced technical inadequacy, the present disclosure provides a power module package to reduce current leakage and improve product reliability.

In one aspect, the present disclosure provides a power module package, which includes an electronic assembly, a first terminal assembly and a second terminal assembly. The electronic assembly includes at least one substrate. The first terminal assembly includes at least one first power device terminal. The second terminal assembly includes at least one second power device terminal. The at least one first power device terminal and the at least one second power device terminal respectively extend from different surfaces of the substrate, and a height difference is formed between the at least one first power device terminal and the at least one second power device terminal. The at least one first power device terminal includes a first contact section and a first non-contact section, the first contact section is directly connected to the substrate, and the first non-contact section is not in contact with the substrate, and the substrate protrudes from the first contact section and extends to a position under the first non-contact section.

Therefore, one of the beneficial effects of the present disclosure is that the power module package provided by the present disclosure has a smaller volume, and can increase the creepage distance between the adjacent power device terminals and improve product reliability by virtue of the substrate protruding from the first contact section and extending to a position under the first non-contact section.

These and other aspects of the present disclosure will become apparent from the following description of the embodiment taken in conjunction with the following drawings and their captions, although variations and modifications therein can be affected without departing from the spirit and scope of the novel concepts of the disclosure.

### BRIEF DESCRIPTION OF THE DRAWINGS

The described embodiments can be better understood by reference to the following description and the accompanying drawings, in which:

FIG. 1 is a schematic perspective view of a power module package according to a first embodiment of the present disclosure;

FIG. 2 is a schematic perspective exploded view of the power module package omitting a package layer according to the first embodiment of the present disclosure;

FIG. 3 is another schematic perspective exploded view of the power module package omitting the package layer according to the first embodiment of the present disclosure;

FIG. 4 is a schematic top view of the power module package omitting the package layer and a heat sink according to the first embodiment of the present disclosure;

FIG. 5 is a schematic bottom view of the power module package omitting the package layer and the heat sink according to the first embodiment of the present disclosure;

FIG. 6 is a schematic top view of the power module package according to the first embodiment of the present disclosure;

FIG. 7 is a schematic cross-sectional view taken along line VII-VII of FIG. 6;

FIG. 8 is a partial schematic cross-sectional view of the power module package according to a second embodiment of the present disclosure;

FIG. 9 is a partial schematic cross-sectional view of the power module package according to a third embodiment of the present disclosure;

FIG. 10 is a partial schematic cross-sectional view of the power module package according to a fourth embodiment of the present disclosure;

FIG. 11 is a partial schematic cross-sectional view of the power module package according to a fifth embodiment of the present disclosure;

FIG. 12 is a partial schematic cross-sectional view of the power module package according to a sixth embodiment of the present disclosure;

FIG. 13 is a schematic perspective view of the power module package omitting the package layer according to a seventh embodiment of the present disclosure;

FIG. 14 is another schematic perspective view of the power module package omitting the package layer according to the seventh embodiment of the present disclosure; and

FIG. 15 is a schematic top view of the power module package omitting the package layer according to the seventh embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

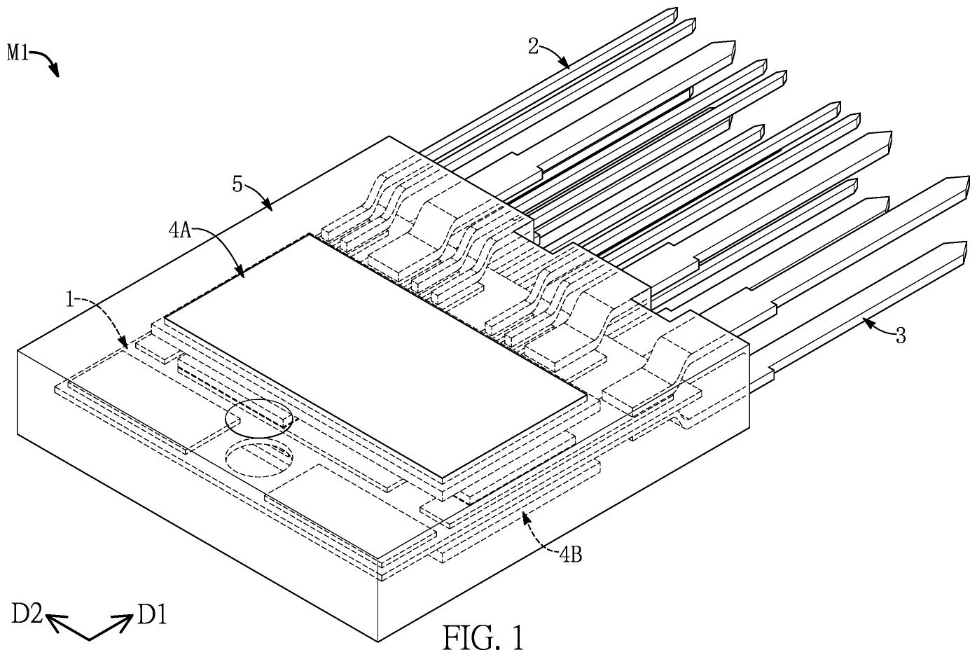

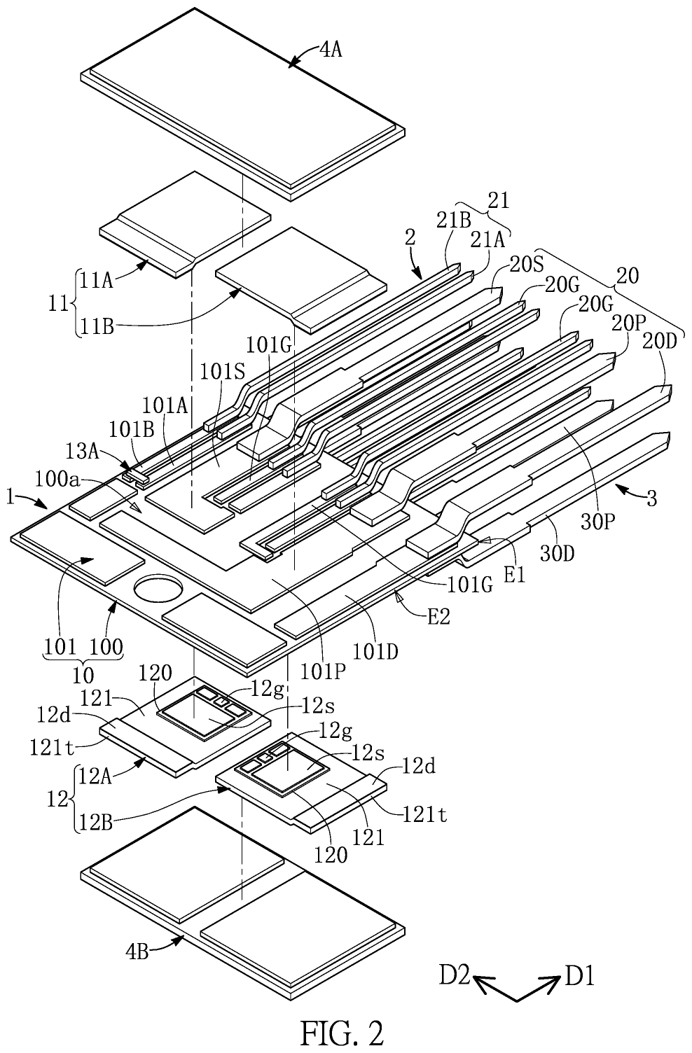

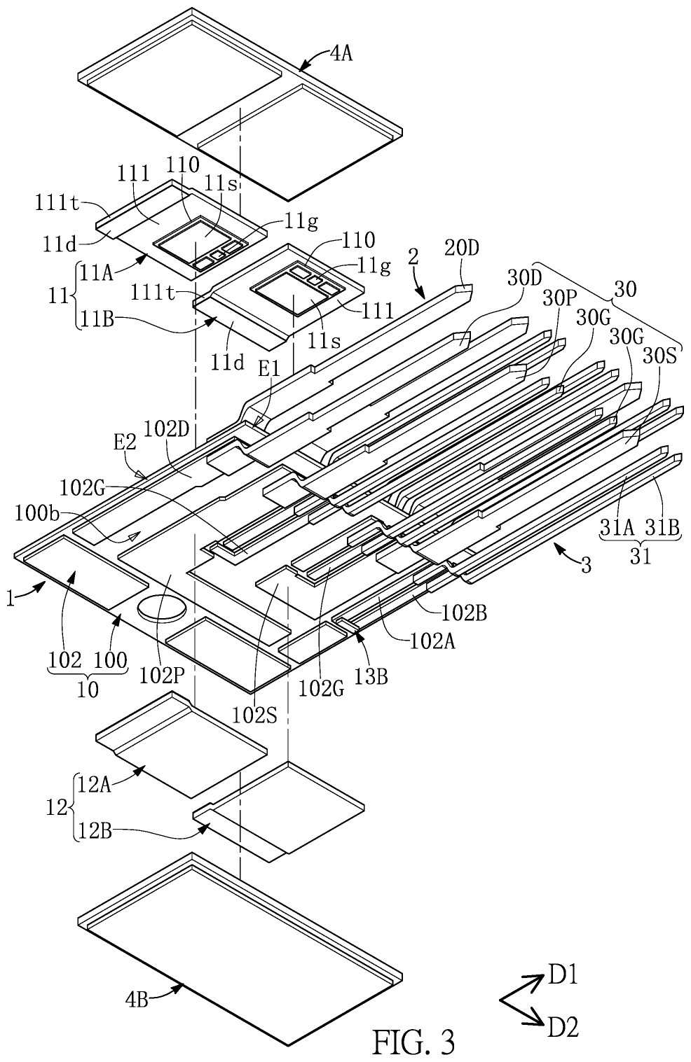

Referring to FIG. 1 to FIG. 3, FIG. 1 is a schematic perspective view of a power module package (or a power package module) according to a first embodiment of the present disclosure, and FIG. 2 and FIG. 3 are schematic perspective exploded views of the power module package at different angles, respectively. The power module package M1 of this embodiment can be applied to a circuit design of electronic products, and is suitable for operating at high voltage and high current. In this embodiment, the power module package M1 includes an electronic assembly 1, a first terminal assembly 2, a second terminal assembly 3, a plurality of heat sinks (4A, 4B) and a package layer 5.

As shown in FIG. 2 and FIG. 3, the electronic assembly 1 of this embodiment includes a substrate 10 (such as a carrier board), a first power device group 11 and a second power device group 12. The substrate 10 can not only carry the first power device group 11 and the second power device group 12, but can also establish electrical connections of a plurality of power devices of the first power device group 11 or the second power device group 12. In this embodiment, taking a part of the circuit for forming the voltage conversion system circuit as an example so as to describe the detailed structure of the substrate 10 according to this embodiment of the present disclosure, and describe the electrical connection relationship among the substrate 10, the first power device group 11 and the second power device group 12.

Referring to FIG. 2 and FIG. 3, the substrate 10 includes an insulating plate 100, a first circuit pattern layer 101 (such as a patterned wiring layer) and a second circuit pattern layer 102 (such as a patterned wiring layer). The material of the insulating plate 100 can be ceramic, polymer or composite material, in which the ceramic can be alumina, aluminum nitride or silicon nitride. The insulating plate 100 has a first surface 100a and a second surface 100b opposite to each other.

As shown in FIG. 2, the first circuit pattern layer 101 is disposed on the first surface 100a of the insulating plate 100. The first circuit pattern layer 101 may include a plurality of first pads according to different requirements. Furthermore, the first circuit pattern layer 101 can be used to construct the current transmission paths of the first power devices (11A, 11B) in the first power device group 11. Accordingly, the shape, number and configuration of the first pads can be adjusted according to the number and the bonding positions of the first power devices (11A, 11B) of the first power device group 11.

As shown in FIG. 2, the first circuit pattern layer 101 of this embodiment may include a first ground pad 101S, two first gate pads 101G, a first voltage switching pad 101P, and a first power input pad 101D, but this example is not meant to limit the scope of the present disclosure. It should be noted that, in this embodiment, a portion of the first ground pad 101S, a portion of the first gate control pad 101G, a portion of the first voltage switching pad 101P, and a portion of the first power input pad 101D can extend toward the same side edge E1 of the insulating plate 100 (or the substrate 10), and an end of each of them is adjacent to the side edge E1 of the insulating plate 100, but this example is not meant to limit the scope of the present disclosure.

When the power module package M1 is operating, the first ground pad 101S, the first voltage switching pad 101P, and the first power input pad 101D should be able to allow a relatively large current to pass therethrough. Therefore, the area of any one of the first ground pad 101S, the first voltage switching pad 101P and the first power input pad 101D is larger than that of each of the first gate pads 101G.

Referring to FIG. 2, in this embodiment, the top view of the first voltage switching pad 101P is shown as an L shape, and the first voltage switching pad 101P has a first connection portion (not labeled) extending along the first direction D1 and a second connection portion (not labeled) extending along the second direction D2. The first connection portion is adjacent to the first power input pad 101D and one of the first gate pads 101G. However, the separation distance between the first connection portion and the first power input pad 101D is greater than the separation distance between the first connection portion and the first gate control pad 101G. In this way, arcing discharge can be avoided between the first voltage switching pad 101P and the first power input pad 101D, which may damage the components.

The second connection portion of the first voltage switching pad 101P extends from one end of the first connection portion to a position close to the first ground pad 101S. However, the separation distance between the second connection portion of the first voltage switching pad 101P and the first ground pad 101S is also greater than the separation distance between the first ground pad 101S and another first gate control pad 101G to avoid arcing discharge between the first voltage switching pad 101P and the first ground pad 101S.

Referring to FIG. 3, in this embodiment, the second circuit pattern layer 102 is disposed on the second surface 100b of the insulating plate 100. That is to say, the first circuit pattern layer 101 and the second circuit pattern layer 102 are respectively located on two opposite sides of the insulating plate 100. Similarly, the second circuit pattern layer 102 can be used to construct current transmission paths of the power devices of the second power device group 12. Accordingly, the second circuit pattern layer 102 may include a plurality of second pads according to different requirements, and the shape, number and configuration of the second pads can be adjusted according to the number and the bonding positions of the second power devices (12A, 12B) of the second power device group 12.

In detail, the second circuit pattern layer 102 may include a second ground pad 102S, two second gate control pads 102G, a second voltage switching pad 102P, and a second power input pad 102D, but this example is not meant to limit the scope of the present disclosure.

It should be noted that, in this embodiment, the power module package M1 is an in-line power module package. Therefore, similar to the first circuit pattern layer 101, a portion of the second ground pad 102S, a portion of the second gate control pad 102G, a portion of the second voltage switching pad 102P and a portion of the second power input pad 102D of the second circuit pattern layer 102 can also extend toward the same side edge E1 of the insulating plate 100 (or the substrate 10), and an end of each of them is adjacent to the side edge E1 of the insulating plate 100, but this example is not meant to limit the scope of the present disclosure.

In addition, when the power module package M1 is operating, the second ground pad 102S, the second voltage switching pad 102P and the second power input pad 102D should be able to allow a relatively large current to pass therethrough. Therefore, the area of any one of the second ground pad 102S, the second voltage switching pad 102P and the second power input pad 102D is larger than that of each of the second gate control pads 102G.

Referring to FIG. 3, similar to the first voltage switching pad 101P, the bottom view of the second voltage switching pad 102P is substantially shown as an L shape, and the second voltage switching pad 102P has a first connection portion (not labeled) extending along the first direction D1 and a second connection portion (not labeled) extending along the second direction D2. The first connection portion is adjacent to the second power input pad 102D and one of the second gate control pads 102G. However, the separation distance between the second connection portion and the second power input pad 102D is greater than the separation distance between the second connection portion and the second gate control pad 102G. In this way, arcing discharge can be avoided between the second voltage switching pad 102P and the second power input pad 102D, which may damage the components.

The second connection portion of the second voltage switching pad 102P extends from the first connection portion to a position close to the second ground pad 102S. However, the separation distance between the second connection portion of the second voltage switching pad 102P and the second ground pad 102S is also greater than the separation distance between the second ground pad 102S and another second gate control pad 102G to avoid arcing discharge between the second voltage switching pad 102P and the second ground pad 102S.

In this embodiment, the material constituting the first circuit pattern layer 101 or the second circuit pattern layer 102 can be selected from a material with high electrical conductivity, such as copper or its alloy so as to reduce parasitic resistance. In this way, both the first circuit pattern layer 101 and the second circuit pattern layer 102 can allow a large current to pass therethrough, so that the power module package M1 can operate under the condition of high voltage and high current.

Referring to FIG. 2 to FIG. 4, the first power device group 11 and the second power device group 12 are disposed on the substrate 10 and respectively located on two opposite sides of the substrate 10, but this example is not meant to limit the scope of the present disclosure. The first power device group 11 and the second power device group 12 may include one or more power devices (such as two power devices shown as an example in FIG. 2 and FIG. 3). The power device is, for example, an insulated gate bipolar transistor (IGBT), a metal-oxide-semiconductor field effect transistor (MOSFET) or any combination thereof. Materials for power devices (or power devices) such as silicon carbide, silicon or gallium nitride.

In one embodiment, the first power device group 11 may include a plurality of first power devices (11A, 11B) (such as two power devices shown as an example in FIG. 2), and the first power devices (11A, 11B) are electrically connected to each other through the first circuit pattern layer 101 to form a part of a normalized circuit (e.g., a voltage conversion circuit). The second power device group 12 may include a plurality of second power devices (12A, 12B) (such as two power devices shown as an example in FIG. 3), and the second power devices (12A, 12B) are electrically connected to each other through the second circuit pattern layer 102 to form another part of a normalized circuit (e.g., a voltage conversion circuit). In this embodiment, the first power devices (11A, 11B) and the second power devices (12A, 12B) are not electrically connected with each other. However, when the power module package M1 is electrically connected to the external circuit, the first power devices (11A, 11B) can also be electrically connected to the second power devices (12A, 12B) through the external circuit, but this example is not meant to limit the scope of the present disclosure.

In another embodiment, the first circuit pattern layer 101 can also be electrically connected to the second circuit pattern layer 102 through one or more conductive holes (not shown) formed in the insulating plate 100, so that the first power device (11A, 11B) is connected with the second power device (12A, 12B) in parallel, thereby increasing the power density of the power module package M1.

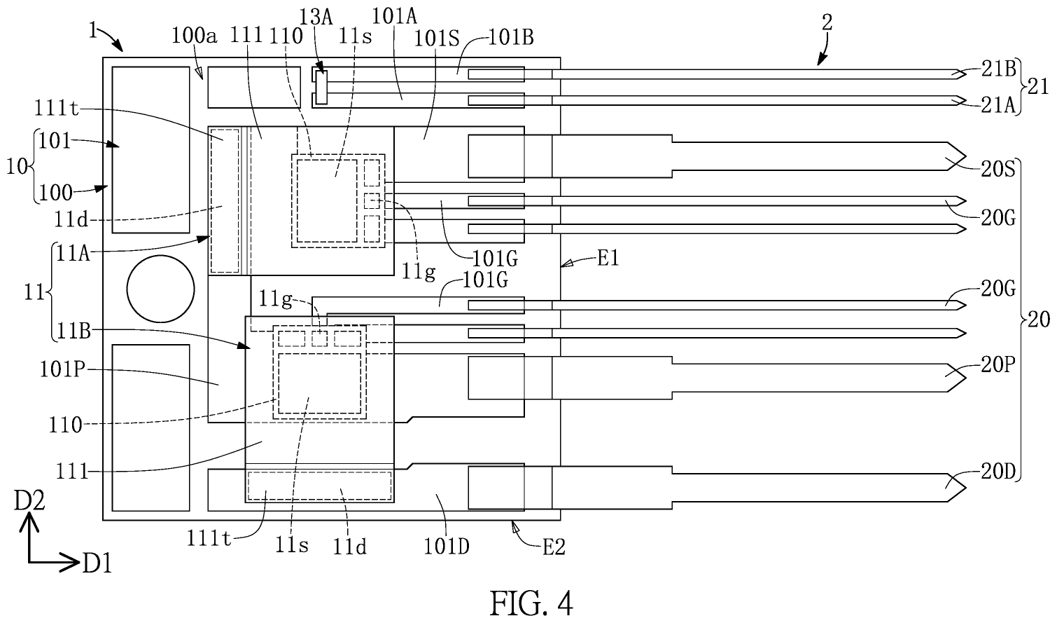

Referring to FIG. 4, the first power devices (11A, 11B) of the first power device group 11 are taken as an example for description. Each of the first power devices (11A, 11B) may include a first source pad 11s, a first drain pad 11d and a first gate pad 11g. It is worth mentioning that the first power devices (11A, 11B) of the present embodiment are pre-packaged components, and the first drain pad 11d, the first gate pad 11g, and the first source pad 11s are all on the same side of the first power devices (11A, 11B). Therefore, the first power devices (11A, 11B) of the present embodiment can be directly disposed on the substrate 10 by the surface mounting technology (SMT) without using bonding wires, thereby reducing the overall volume of the power module package M1.

In detail, each of the first power devices (11A, 11B) may include a first power chip 110 and a first conductive connector 111 connected to the first power chip 110, and the first source pad 11s and the first gate pad 11g are located on the active surface of the first power chip 110. The first conductive connector 111 is disposed on the backside of the first power chip 110 and has a first pin portion 111t, and the first drain pad 11d is disposed at the end of the first pin portion 111t.

As shown in FIG. 4, in this embodiment, the two first power devices (11A, 11B) can be configured in different orientations. Furthermore, the first power device 11A is configured by using the first power chip 110 to face toward the side edge E1 of the substrate 10. The first power device 11B is configured by using the first power chip 110 to face toward the first power device 11A. That is to say, the first pin portion 111t of the first power device 11B is disposed toward the other side edge E2 of the substrate 10.

As shown in FIG. 4, the two first power devices (11A, 11B) can be connected with each other in series through the first circuit pattern layer 101. In detail, when the first power devices (11A, 11B) are disposed on the first circuit pattern layer 101, the two first gate pads 11g of the two first power devices (11A, 11B) can be respectively connected to the two first gate control pads 101G. The first source pad 11s of the first power device 11A is electrically connected to the first ground pad 101S, and the first drain pad 11d is electrically connected to the first voltage switching pad 101P. The first source pad 11s of the first power device 11B is electrically connected to the first voltage switching pad 101P, and the first drain pad 11d is electrically connected to the first power input pad 101D.

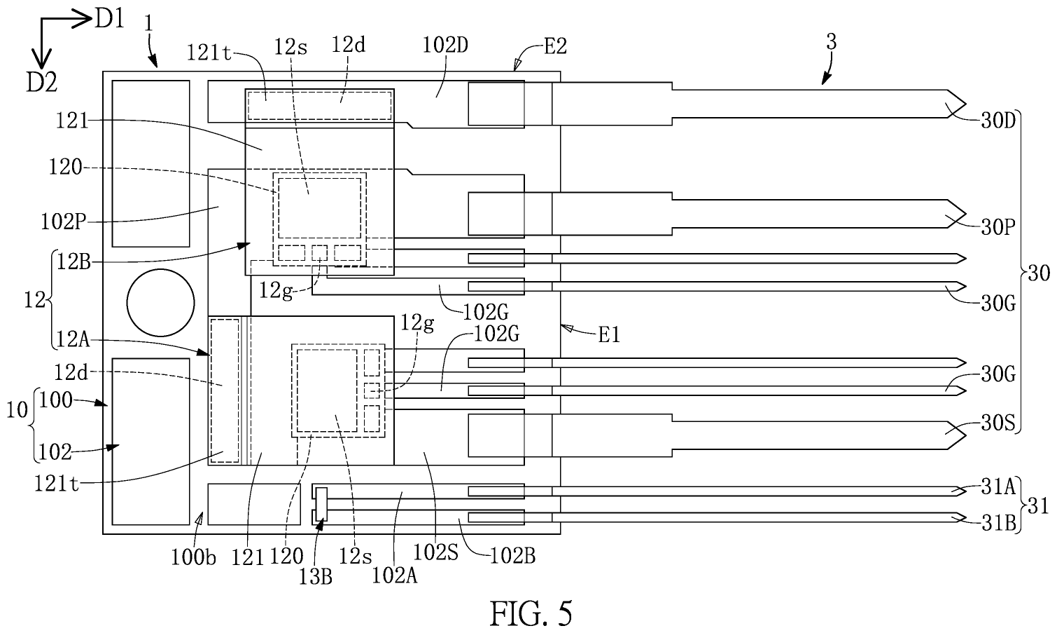

Referring to FIG. 3 and FIG. 5, in this embodiment, each of the second power devices (12A, 12B) may include a second source pad 12s, a second drain pad 12d and a second gate pad 12g. Each of the second power devices (12A, 12B) may include a second power chip 120 and a second conductive connector 121 connected to the second power chip 120, and the second source pad 12s and second gate pad 12g are located on the active surface of the second power chip 120. The second conductive connector 121 is disposed on the backside of the second power chip 120 and has a second pin portion 121t, and the second drain pad 12d is disposed at the end of the second pin portion 121t.

Referring to FIG. 4 and FIG. 5, in this embodiment, the pattern of the first circuit pattern layer 101 and the pattern of the second circuit pattern layer 102 are mirror-symmetrical with respect to the insulating plate 100, but this example is not meant to limit the scope of the present disclosure. The configuration of the second power devices (12A, 12B) is similar to that of the first power devices (11A, 11B). The second power device 12A is configured by using the second power chip 120 to face toward the side edge E1 of the substrate 10. The second power device 12B is configured by using the second power chip 120 to face toward the second power device 12A.

In addition, the two second power devices (12A, 12B) can be connected with each other in series through the second circuit pattern layer 102. In detail, when the second power devices (12A, 12B) are disposed on the second circuit pattern layer 102, the two second gate pads 12g of the two second power devices (12A, 12B) can be respectively connected to the two second gate control pads 102G. The second source pad 12s of the second power device 12A is electrically connected to the second ground pad 102S, and the second drain pad 12d is electrically connected to the second voltage switching pad 102P. The second source pad 12s of the second power device 12B is electrically connected to the second voltage switching pad 102P, and the second drain pad 12d is electrically connected to the second power input pad 102D.

Referring to FIG. 4 again, the electronic assembly 1 of this embodiment further includes at least one temperature sensor 13A. In addition, the first circuit pattern layer 101 further includes a first positive electrode pad 101A and a first negative electrode pad 101B. The two electrodes of the temperature sensor 13A can be electrically connected to the first positive electrode pad 101A and the first negative electrode pad 101B, respectively. In this embodiment, when the first power device group 11 is operating, the temperature sensor 13A can be used to detect the temperature inside the power module package M1, so as to prevent the first power devices (11A, 11B) from being damaged due to overheating.

As shown in FIG. 5, the electronic assembly 1 may further include another temperature sensor 13B disposed on the second circuit pattern layer 102 to monitor the ambient temperature of the second power device 12A during operation. Accordingly, the second circuit pattern layer 102 may also have a second positive pad 102A and a second negative pad 102B for electrically connecting the temperature sensor 13B, but this example is not meant to limit the scope of the present disclosure example.

Referring to FIG. 4, the first terminal assembly 2 is disposed on the substrate 10 and connected to the first circuit pattern layer 101, so that the temperature sensor 13A and the first power devices (11A, 11B) can be electrically connected to another external circuit. Furthermore, the first terminal assembly 2 may include a plurality of first power device terminals 20. Each of the first power device terminals 20 can be electrically connected to the corresponding first power device (11A, 11B) through the first circuit pattern layer 101.

The first power device terminals 20 can be defined for receiving or outputting a variety of different signals. For example, the first power device terminals 20 may at least include a first ground pin 20S, two first gate pins 20G, a first voltage switching pin 20P, and a first power input pin 20D, but this example is not meant to limit the scope of the present disclosure.

As shown in FIG. 4, the first ground pin 20S is electrically connected to the first ground pad 101S. The two first gate pins 20G are respectively connected to the two first gate pads 101G. In addition, the first voltage switching pin 20P and the first power input pin 20D are respectively connected to the first voltage switching pad 101P and the first power input pad 101D. It should be noted that the first ground pin 20S, the first voltage switching pin 20P and the first power input pin 20D have a larger cross-sectional area to allow a relatively large current to pass therethrough.

In addition, the first terminal assembly 2 of this embodiment may further include a temperature sensing pin group 21, which is electrically connected to the temperature sensor 13A through the first circuit pattern layer 101. As shown in FIG. 4, the temperature sensing pin group 21 may include a first positive electrode pin 21A and a first negative electrode pin 21B respectively connected to the first positive electrode pad 101A and the first negative electrode pad 101B.

Referring to FIG. 5, the second terminal assembly 3 is disposed on the substrate 10 and connected to the second circuit pattern layer 102, so that the temperature sensor 13A and the second power devices (12A, 12B) can be electrically connected to another external circuit. That is to say, the second terminal assembly 3 and the first terminal assembly 2 are respectively located on two opposite surfaces of the substrate 10.

The second terminal assembly 3 may include a plurality of second power device terminals 30. Each of the second power device terminals 30 can be electrically connected to the corresponding second power device (12A, 12B) through the second circuit pattern layer 102. The second power device terminals 30 may include at least one second ground pin 30S, two second gate pins 30G, a second voltage switching pin 30P and a second power input pin 30D, but this example is not meant to limit the scope of the present disclosure.

As shown in FIG. 5, the second ground pin 30S is electrically connected to the second ground pad 102S. The two second gate pins 30G are respectively connected to the two second gate control pads 102G. In addition, the second voltage switching pin 30P and the second power input pin 30D are respectively connected to the second voltage switching pad 102P and the second power input pad 102D. It should be noted that the second ground pin 30S, the second voltage switching pin 30P and the second power input pin 30D have a larger cross-sectional area to allow a relatively large current to pass therethrough.

In addition, the second terminal assembly 3 of this embodiment may further include another temperature sensing pin group 31, which is electrically connected to the temperature sensor 13B through the second circuit pattern layer 102. As shown in FIG. 5, the temperature sensing pin group 31 may include a second positive electrode pin 31A and a second negative electrode pin 31B respectively connected to the second positive electrode pad 102A and the second negative electrode pad 102B.

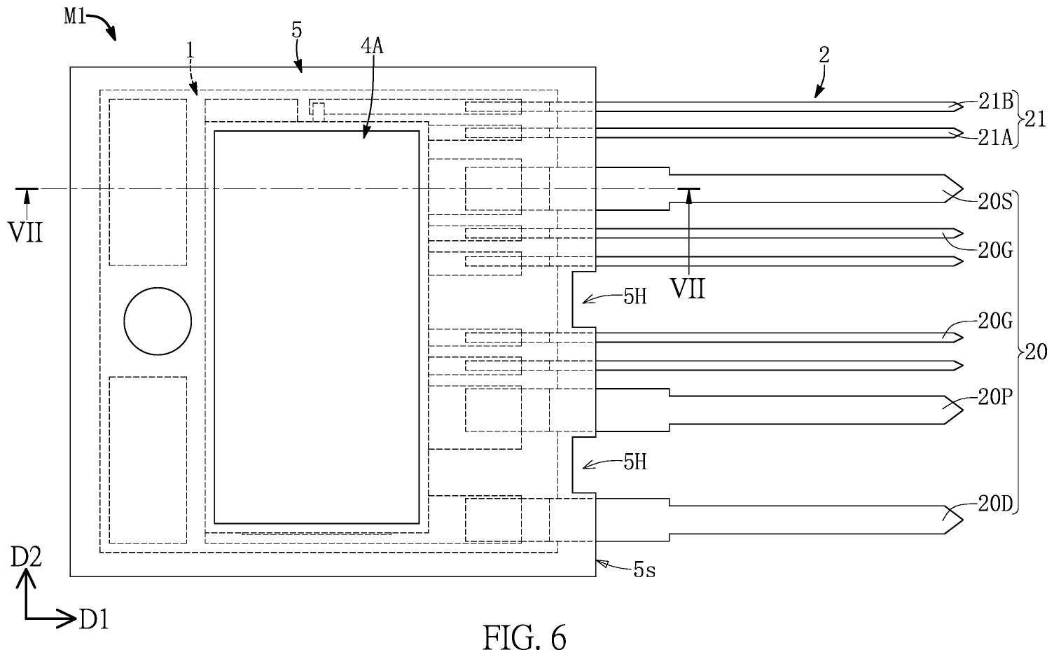

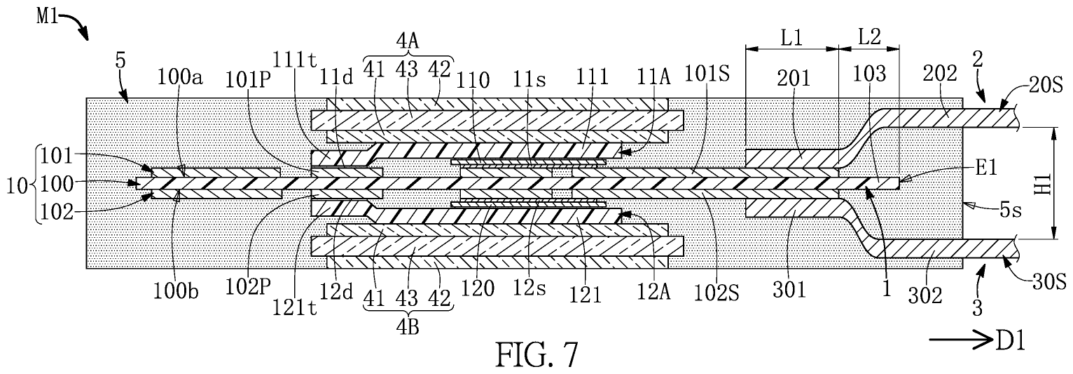

Referring to FIG. 6 and FIG. 7, which are a schematic top view and a partial cross-sectional view of the power module package M1 according to the first embodiment of the present disclosure, respectively. As shown in FIG. 7, the power module package M1 of the first embodiment further includes two heat sinks (4A, 4B), and the two heat sinks (4A, 4B) are respectively located on two opposite sides of the electronic assembly 1. The two heat sinks (4A, 4B) are respectively disposed on the first power device 11A and the second power device 12A to dissipate the heat generated from the first power device 11A and the second power device 12A. That is to say, the first power device 11A and the second power device 12A are disposed between the heat sinks (4A, 4B) and the substrate 10. In one embodiment, each of the heat sinks (4A, 4B) is, for example, a direct bonded copper (DBC) or direct plated copper (DPC) substrate, but this example is not meant to limit the scope of the present disclosure.

As shown in FIG. 7, each of the heat sinks (4A, 4B) may include a first conductive layer 41, a second conductive layer 42, and an insulating heat conductor 43 disposed between the first conductive layer 41 and the second conductive layer 42. The first conductive layer 41 has two pads (not labeled) separate from each other and respectively disposed on the two first power devices (11A, 11B) (or the two second power devices (12A, 12B). The insulating heat conductor 43 is, for example, a ceramic plate or an insulating glue material with a high thermal conductivity, which is not limited in the present disclosure. The second conductive layer 42 is disposed on the insulating heat conductor 43 and has an area larger than that of the first conductive layer 41.

In addition, the power module package M1 further includes a package layer 5 (or an encapsulation layer), and the package layer 5 at least covers the electronic assembly 1. Since the power module package M1 of this embodiment is an in-line power module package, each of the first power device terminals 20 and the second power device terminals 30 has a portion protruding from a side surface 5s of the package layer 5 so as to be exposed outside the package layer 5. In addition, the heat sinks (4A, 4B) are partially exposed outside the package layer 5. As shown in FIG. 7, the second conductive layers 42 of the heat sinks (4A, 4B) are exposed outside the package layer 5, so that the heat generated by the operation of the power module package M1 can be effectively dissipated to the outside.

When the power module package M1 is applied to another system circuit (not shown), the first terminal assembly 2 and the second terminal assembly 3 of the power module package M1 are correspondingly connected to two specific voltage terminals, so that the first power devices (11A, 11B), the second power devices (12A, 12B) and other electronic components (e.g., temperature sensors 13A, 13B) of the power module package M1 can be electrically connected to the system circuit.

Referring to FIG. 6 again, in this embodiment, the side surface 5s of the package layer 5 further has at least one recessed area 5H (such as two recessed areas shown as an example in FIG. 6). Viewed from a top view, at least one recessed area 5H can be located between two first power device terminals 20 (e.g., the first voltage switching pin 20P and the first power input pin 20D) that need to receive a large current (e.g., allowing the large current to pass through the first voltage switching pin 20P and the first power input pin 20D) and are adjacent to each other, so that the creepage distance between the first voltage switching pin 20P and the first power input pin 20D can be increased. Referring to FIG. 1 and FIG. 6, it should be noted that the recessed region 5H of this embodiment extends from the top surface to the bottom surface of the package layer 5, and is located at the second voltage switching pin 30P and the second power input pin 30D in order to increase the creepage distance between the second voltage switching pin 30P and the second power input pin 30D that are adjacent to each other. In this way, current leakage can be avoided between two adjacent ones of the first power device terminals 20 or two adjacent ones of the second power device terminals 30, which may reduce product reliability.

Referring to FIG. 6 and FIG. 7, in this embodiment, any one of the first power device terminals 20 (e.g., the first ground pin 20S) and the corresponding second power device terminal 30 (e.g., the second ground pin 30S) are aligned with each other in the thickness direction of the substrate 10. Referring to FIG. 7, it is worth mentioning that in this embodiment, any one of the first power device terminals 20 (e.g., the first ground pin 20S) and the corresponding second power device terminal 30 (e.g., the second ground pin 30S) have a height difference H1 in the thickness direction of the substrate 10.

In this embodiment, each of the first power device terminals 20 and each of the second power device terminals 30 are bending terminals. As shown in FIG. 7, each of the first power device terminals 20 includes a first contact section 201 and a first non-contact section 202 that are connected with each other. Similarly, each of the second power device terminals 30 includes a second contact section 301 and a second non-contact section 302 that are connected with each other. The first contact section 201 and the second contact section 301 can be directly connected to the substrate 10, and the first non-contact section 202 and the second non-contact section 302 are not in contact with the substrate 10.

It is worth mentioning that the substrate 10 protrudes from the first contact section 201 in the first direction D1 and extends to a position under the first non-contact section 202. As shown in FIG. 7, the side edge E1 of the substrate 10 protrudes from the first contact section 201 and the second contact section 301 in the first direction D1, and the substrate 10 extends to a position between the first non-contact section 202 and the second non-contact section 302. The first contact section 201 (or the second contact section 301) has a length L1 in the first direction D1. In addition, the perpendicular projection of the first non-contact section 202 (or the second non-contact section 302) on the substrate 10 has a projected length L2 in the first direction D1.

In this embodiment, the first non-contact section 202 and the second non-contact section 302 extend in different directions, and then are bent to extend in the same direction (i.e., the first direction D1). Accordingly, each of the first non-contact section 202 and the second non-contact section 302 has a bending portion. The bending portion can increase the height difference H1 between the first non-contact section 202 and the second non-contact section 302, so that the power module package M1 has a larger operating voltage, but this example is not meant to limit the scope of the present disclosure.

It should be noted that the height difference H1 between the first non-contact section 202 and the second non-contact section 302 is an electrical gap between the first power device terminal 20 and the second power device terminal 30. When the operating voltage of the power module package M1 is higher, the height difference H1 between the first non-contact section 202 and the second non-contact section 302 should be increased to avoid arcing discharge.

In this embodiment, the perpendicular projection of the bending portion of the first non-contact section 202 or the second non-contact section 302 falls on the substrate 10. In other words, the substrate 10 extends beyond the bending portion of the first non-contact section 202 (or the second non-contact section 302) in the first direction D1. Furthermore, the substrate 10 of this embodiment further includes an extending portion 103, and the extending portion 103 extends beyond the bending portion of the first non-contact section 202 (or the second non-contact section 302).

In this way, the creepage distance between the first power device terminal 20 (i.e., the first ground pin 20S) and the second power device terminal 30 (i.e., the second ground pin 30S) can also be increased. In one embodiment, the extending portion 103 and the insulating plate 100 are integrally formed and made of the same material, but this example is not meant to limit the scope of the present disclosure.

### Second Embodiment

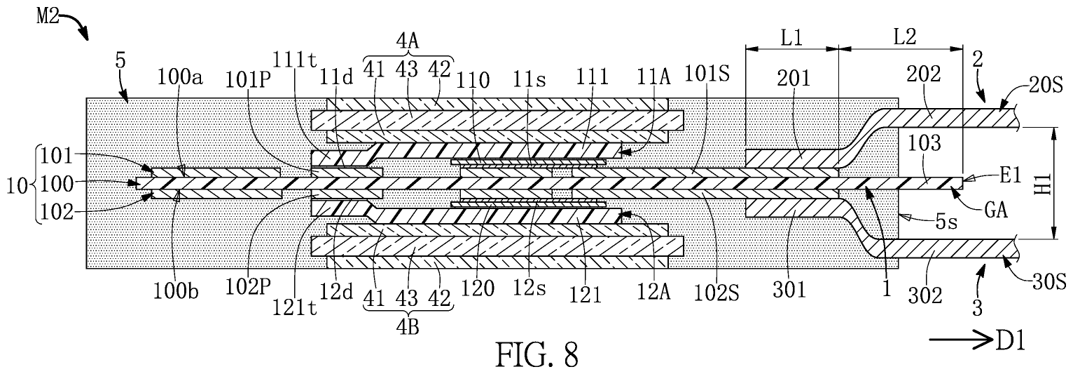

Referring to FIG. 8, which is a partial schematic cross-sectional view of the power module package according to a second embodiment of the present disclosure. Components of this embodiment that are identical to those of the embodiment of FIG. 7 have the same or similar reference numerals, and will not be repeated. In the power module package M2 of this embodiment, the package layer 5 does not completely cover the substrate 10. Compared with the first embodiment, the side edge E1 of the substrate 10 in this embodiment is exposed outside the package layer 5.

In detail, the extending portion 103 of the substrate 10 can pass through the package layer 5 and protrude from the side surface 5s of the package layer 5 to form an electrical isolation portion GA in order to increase the creepage distance between the first non-contact section 202 and the second non-contact sections 302. In this way, current leakage can be avoided so as to prevent product reliability from being decreased without greatly increasing the overall volume of the power module package M2.

### Third Embodiment

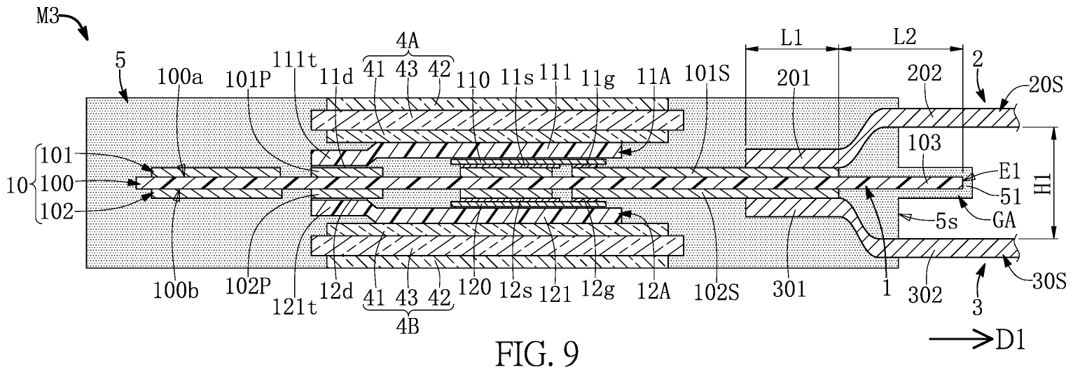

Referring to FIG. 9, which is a partial schematic cross-sectional view of the power module package according to a third embodiment of the present disclosure. Components of this embodiment that are identical to those of the embodiment of FIG. 8 have the same or similar reference numerals, and will not be repeated. In the power module package M3 of the present embodiment, the package layer 5 can conformally enclose the extending portion 103 of the substrate 10, and the package layer 5 has a protruding portion 51 formed on the side surface 5s thereof.

Accordingly, in this embodiment, the extending portion 103 protrudes from the side surface 5s of the package layer 5, but the protruding portion 51 conformally encloses the extending portion 103 to form an electrical isolation part GA between the first power device terminal 20 and the second power device terminal 30. In this way, the creepage distance between the first non-contact section 202 and the second non-contact section 302 can also be increased, and current leakage can be avoided so as to prevent product reliability from being decreased without greatly increasing the overall volume of the power module package M3.

### Fourth Embodiment

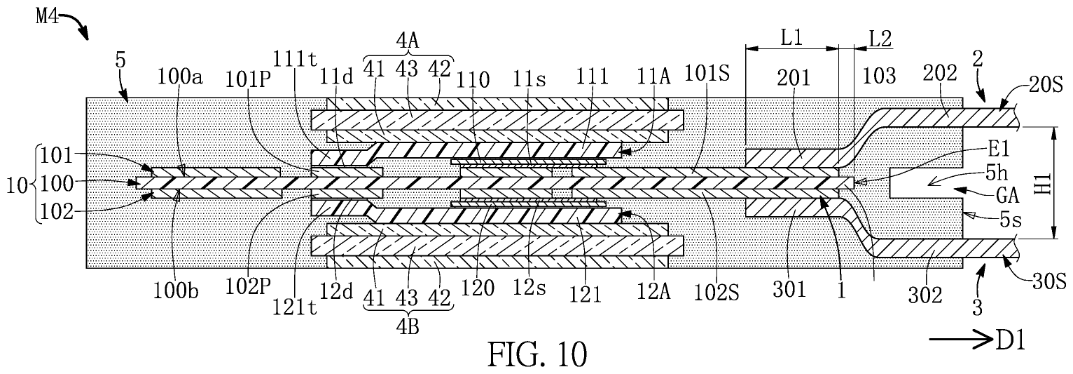

Referring to FIG. 10, which is a partial schematic cross-sectional view of the power module package omitting the package layer according to a fourth embodiment of the present disclosure. The same components of the power module package M4 of the present embodiment and the power module package M1 of the first embodiment have the same or similar reference numerals, and will not be repeated. In this embodiment, the side surface 5s of the package layer 5 has one or more openings 5h. The opening 5h is recessed from the side surface 5s of the package layer 5 and extends into the package layer 5 to form an electrical isolation portion GA, thereby increasing the creepage distance between the first non-contact section 202 and the second non-contact section 302.

In one embodiment, the opening 5h can extend along the second direction D2 so as to increase the creepage distance between each first power device terminal 20 and the corresponding second power device terminal 30. That is to say, the extending direction of the opening 5h and the extending direction of the recessed region 5H shown in FIG. 6 are staggered from each other. Furthermore, the opening 5h can traverse the entire side surface 5s in the second direction D2, but this example is not meant to limit the scope of the present disclosure.

In another embodiment, at least one of the openings 5h has a width in the second direction D2 smaller than the length of the package layer 5 in the second direction D2, and can be formed only between one set of the first power device terminals 20 and the second power device terminals 30 that require a large current to pass through and are aligned up and down. For example, the at least one opening 5h can be formed between the first ground pin 20S and the second ground pin 30S, between the first voltage switching pin 20P and the second voltage switching pin 30P, or between the first power input pin 20D and the second power input pin 30D.

### Fifth Embodiment

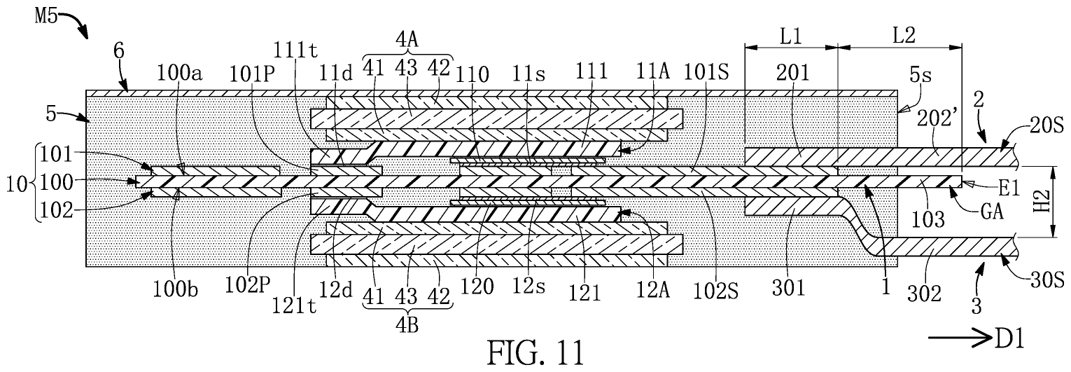

Referring to FIG. 11, which is a partial schematic cross-sectional view of the power module package omitting the package layer according to a fifth embodiment of the present disclosure. The same components of the power module package M5 of the present embodiment and the power module package M2 of the second embodiment have the same or similar reference numerals, and will not be repeated.

In this embodiment, the first power device terminals 20 are straight terminals, and the second power device terminals 30 are bending terminals. That is to say, the first non-contact section 202′ does not have a bending portion, but the present disclosure is not limited thereto. In another embodiment, the first power device terminals 20 can be bending terminals, and the second power device terminals 30 can be straight terminals.

In addition, in this embodiment, the height difference H2 between the first non-contact section 202′ and the second non-contact section 302 can be decreased, thereby reducing the volume of the power module package M5. Compared with the previous embodiments, the operating voltage of the power module package M5 of the present embodiment is relatively low. However, by forming the electrical isolation portion GA between the first power device terminal 20 and the second power device terminal 30, it is also possible to avoid current leakage so as to prevent product reliability from being decreased.

In addition, the power module package M5 further includes a heat sink 6, and the heat sink 6 can be disposed on the outer surface of the package layer 5 so as to enhance the heat dissipation effect. In this embodiment, the heat sink 6 is disposed on the top surface of the package layer 5, closer to the first power device terminal 20, and farther from the second power device terminal 30. That is to say, the heat sink 6 is disposed above the heat sink 4A and directly contacts the second conductive layer 42 and a part of the top surface of the package layer 5.

### Sixth Embodiment

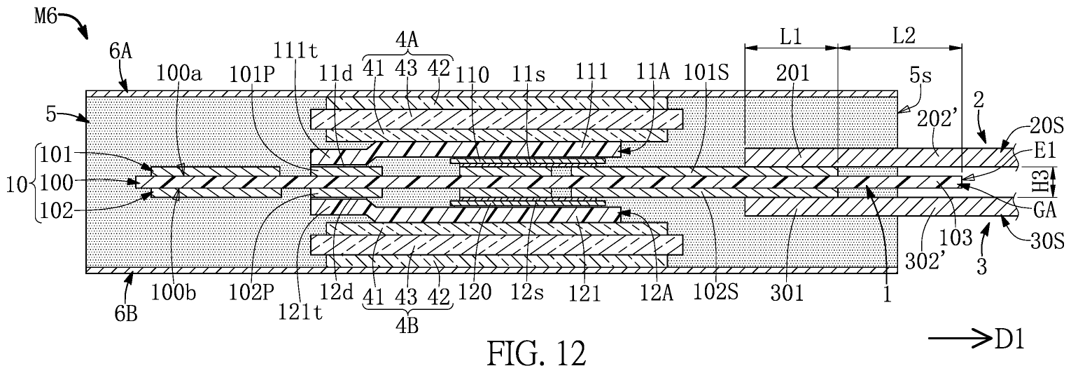

Referring to FIG. 12, which is a partial schematic cross-sectional view of the power module package omitting the package layer according to a sixth embodiment of the present disclosure. The same components of the power module package M6 of the present embodiment and the power module package M5 of the fifth embodiment have the same or similar reference numerals, and will not be repeated.

In this embodiment, each of the first power device terminals 20 and each of the second power device terminals 30 are straight terminals. Accordingly, the height difference H3 between the first non-contact section 202′ and the second non-contact section 302′ is smaller, and the volume of the power module package M6 can be further reduced. However, compared with the previous embodiments, the operating voltage of the power module package M6 of this embodiment is relatively low.

In addition, the power module package M6 may further include two heat sinks (6A, 6B), and the two heat sinks (6A, 6B) can be respectively disposed on the top surface and the bottom surface of the package layer 5, thereby enhancing the heat dissipation effect. That is to say, one of the heat sinks 6A is disposed above the heat sink 4A and directly contacts the second conductive layer 42 and a part of the top surface of the package layer 5. The other heat sink 6B is in direct contact with the second conductive layer 42 of the heat sink 4B and a part of the bottom surface of the package layer 5.

### Seventh Embodiment

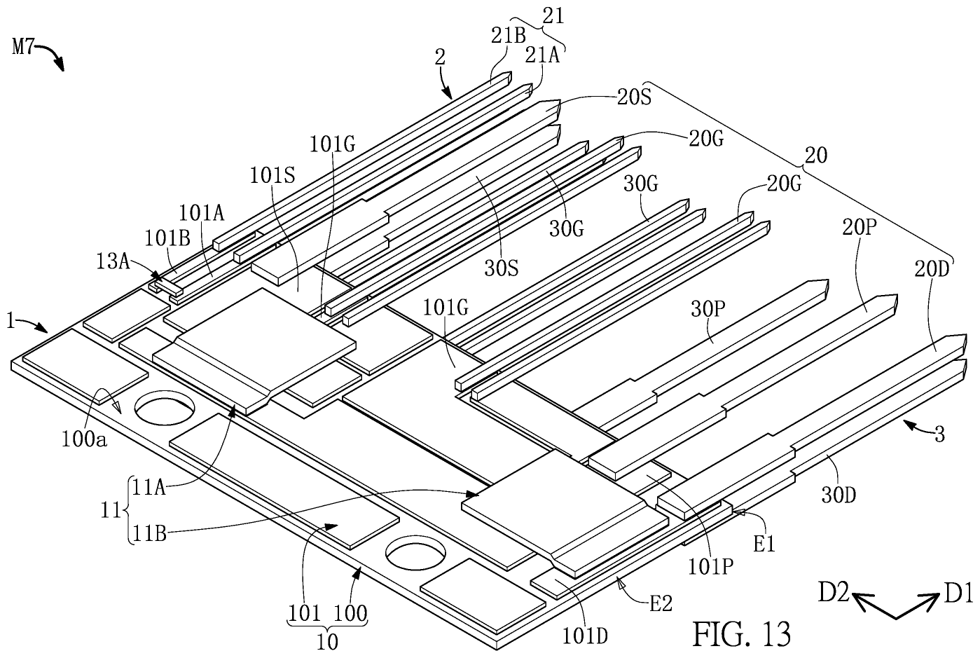

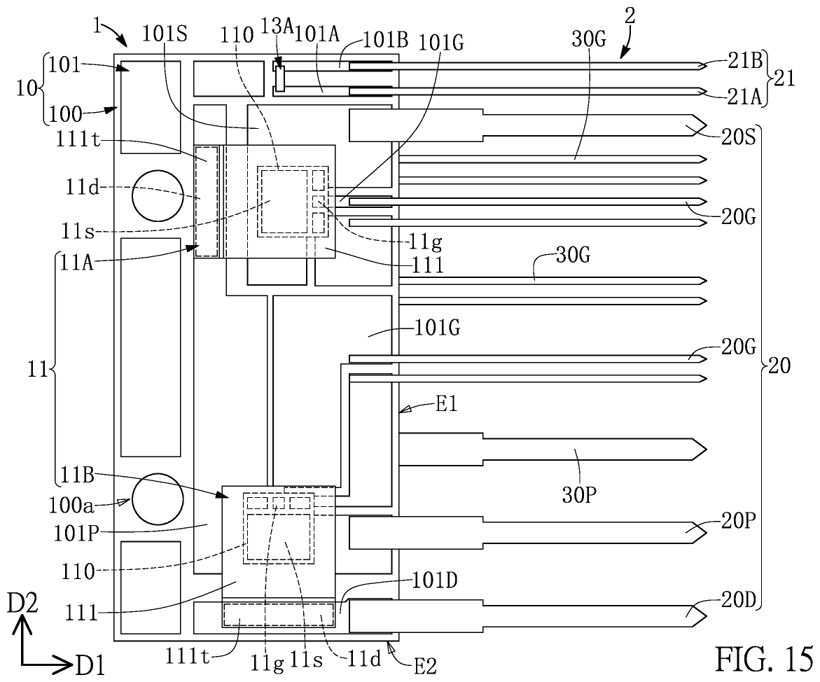

Referring to FIG. 13 to FIG. 15, which are exploded perspective views of the power module package omitting the package layer and the heat sink according to a seventh embodiment of the present disclosure. The same components of the power module package M7 of the present embodiment and the power module package M1 of the first embodiment have the same or similar reference numerals, and will not be repeated.

In the power module package M7 of the present embodiment, at least one first power device terminal 20 (e.g., a first voltage switching pin 20P) and a corresponding second power device terminal 30 (e.g., a second voltage switching pin 30P) will be staggered from each other. In this way, the shortest distance between the first voltage switching pin 20P and the second voltage switching pin 30P can be greatly increased to avoid arcing discharge and further improve product reliability. In this embodiment, the corresponding first gate pin 20G and the corresponding second gate pin 30G are also staggered from each other, but this example is not meant to limit the scope of the present disclosure.

It should be noted that, although in the seventh embodiment shown in FIG. 13 to FIG. 15, both the first power device terminal 20 and the second power device terminal 30 are bending terminals, but this example is not meant to limit the scope of the present disclosure. Furthermore, the corresponding first power device terminal 20 and the corresponding second power device terminal 30 that are staggered from each other can be straight terminals. In addition, since some of the first power device terminals 20 (e.g., the first voltage switching pin 20P) and the corresponding second power device terminals 30 are staggered from each other, even if the height difference between each first power device terminal 20 and each second power device terminal 30 is reduced, the power module package M7 of this embodiment can still operate at a relatively high voltage. That is to say, compared with the sixth embodiment, the operating voltage of the power module package M7 of this embodiment is relatively high.

Compared with the power module packages M1 to M6 of the first to sixth embodiments, the power module package M7 of this embodiment has a larger size. However, compared with the existing power module package by wire bonding, the power module package M7 of the embodiment of the present disclosure has a smaller size.

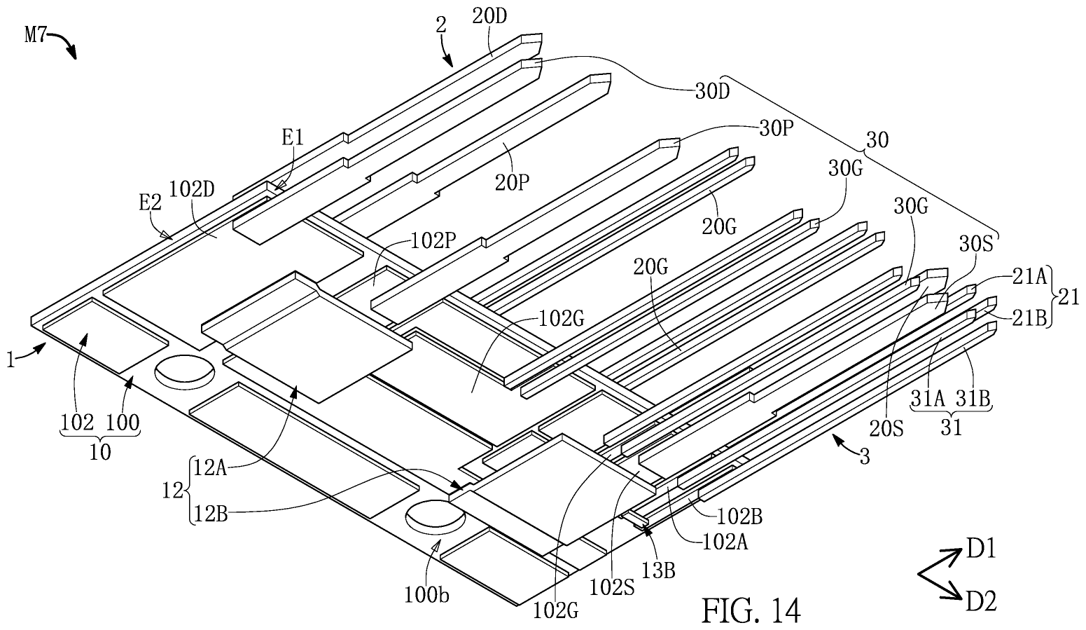

As shown in FIG. 13 and FIG. 14, the shapes and positions of the first pads of the first circuit pattern layer 101, and the shapes and positions of the second pads of the second circuit pattern layer 102 are different from the first embodiment. For example, in this embodiment, compared with the first power input pad 101D, the second power input pad 102D has a larger area. Accordingly, in this embodiment, the first circuit pattern layer 101 and the second circuit pattern layer 102 are not mirror-symmetrical with respect to the substrate 10.

### Beneficial Effects of the Embodiments

One of the beneficial effects of the present disclosure is that the power module packages M1 to M7 provided by the present disclosure have a smaller volume, and can increase the creepage distance between the adjacent power device terminals and improve product reliability by virtue of the substrate 10 protruding from the first contact section 201 and extending to a position under the first non-contact section 202.

In addition, by virtue of the electrical isolation portion GA being located on the side surface 5s of the package layer 5 and being located between the first power device terminal 20 and the second power device terminal 30, the creepage distance between the corresponding first power device terminal 20 and the corresponding second power device terminal 30 can be increased. In this way, current leakage can be avoided, and product reliability and withstand voltage capability of the power module packages M1 to M7 can be improved.

In addition, the power module packages M1 to M7 provided by the embodiments of the present disclosure can have a smaller volume without wire bonding. Furthermore, in the substrate 10 of the embodiment of the present disclosure, the first circuit pattern layer 101 and the second circuit pattern layer 102 are used as current transmission paths of the first power devices (11A, 11B) and the second power devices (12A, 12B), and the power module packages M1 to M7 can form a part of a normalized circuit according to the embodiments of the present disclosure so as to be able to apply to different circuit systems.

In one embodiment, by forming the first circuit pattern layer 101 and the second circuit pattern layer 102 on two opposite sides of the insulating plate 100, the number of power devices can also be increased without increasing the area of the insulating plate 100, so that the power density of the power module packages M1 to M7 is increased.

On the other hand, the temperature sensors (13A, 13B) for detecting the temperature can be arranged on the substrate 10 according to different requirements. When the first power device group 11 (or the second power device group 12) is operating, the temperature sensors (13A, 13B) can be used to detect the temperature inside the power module package M1 to prevent the first power devices (11A, 11B) (or the second power devices (12A, 12B) from being damaged due to overheating.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A power module package, comprising:
an electronic assembly including at least one substrate:
a first terminal assembly including at least one first power device terminal; and
a second terminal assembly including at least one second power device terminal, wherein the at least one first power device terminal and the at least one second power device terminal respectively extend from different surfaces of the substrate, and a height difference is formed between the at least one first power device terminal and the at least one second power device terminal;
wherein the at least one first power device terminal includes a first contact section and a first non-contact section, the first contact section is directly connected to the substrate, and the first non-contact section is not in contact with the substrate, and the substrate protrudes from the first contact section and extends to a position under the first non-contact section.

2. The power module package according to claim 1, further comprising:
a package layer for enclosing the electronic assembly, wherein each of the at least one first power device terminal and the at least one second power device terminal has a portion protruding from a side surface of the package layer and being exposed outside the package layer; and
an electrical isolation portion is located on the side surface of the package layer and between the at least one first power device terminal and the at least one second power device terminal.

3. The power module package according to claim 2, wherein an extending portion of the substrate passes through the package layer and protrudes from the side surface of the package layer to form the electrical isolation portion.

4. The power module package according to claim 2, wherein the substrate includes an extending portion protruding from the side surface, and the package layer further includes a protruding portion conformally enclosing the extending portion to form the electrical isolation portion.

5. The power module package according to claim 2, wherein the package layer has an opening formed on the side surface thereof, and the opening is recessed from the side surface of the package layer and is formed inside the package layer to form the electrical isolation portion.

6. The power module package according to claim 2, wherein the first terminal assembly includes a plurality of the first power device terminals, the package layer has a recessed area formed on the side surface thereof, and the recessed area is located between two adjacent ones of the first power device terminals.

7. The power module package according to claim 1, wherein the at least one first power device terminal and the at least one second power device terminal are aligned with each other in a thickness direction of the substrate.

8. The power module package according to claim 1, wherein each of the at least one first power device terminal and the at least one second power device terminal is a bending terminal.

9. The power module package according to claim 8, wherein the bending terminal has a bending portion, and the substrate extends beyond the bending portion.

10. The power module package according to claim 1, further comprising: a package layer and a heat sink, wherein the package layer encloses the electronic assembly, the at least one first power device terminal is a straight terminal, the at least one second power device terminal is a bending terminal, the heat sink is arranged on an outer surface of the package layer, and the heat sink is close to the at least one first power device terminal and away from the at least one second power device terminal.

11. The power module package according to claim 1, wherein each of the at least one first power device terminal and the at least one second power device terminal is a straight terminal.

12. The power module package according to claim 1, wherein the at least one first power device terminal and the at least one second power device terminal are staggered from each other.

13. The power module package according to claim 1, wherein the substrate further includes:
an insulating plate having a first surface and a second surface opposite to each other, wherein the insulating plate has a side edge extending along a direction;
a first circuit pattern layer disposed on the first surface of the insulating plate, wherein the first terminal assembly is connected to the first circuit pattern layer; and
a second circuit pattern layer disposed on the second surface of the insulating plate, wherein the second terminal assembly is connected to the second circuit pattern layer.

14. The power module package according to claim 1, wherein the electronic assembly further includes a temperature sensor disposed on the substrate, and the first terminal assembly further includes a temperature sensing pin group electrically connected to the temperature sensor.
